(19) United States
(12) Patent Application Publication
(10) Pub. No.: US 2026/0040530 A1
(43) Pub. Date: Feb. 5, 2026

(54) SEMICONDUCTOR DEVICE WITH INDEPENDENT SOURCE-DRAIN REGION PROFILES FOR LOW VOLTAGE AND HIGH VOLTAGE FINFET TRANSISTORS

(71) Applicant: Micron Technology, Inc., Boise, ID (US)

(72) Inventors: Takehiro HIRAMATSU, Hiroshima (JP); Toshihiko MIYASHITA, Hiroshima (JP)

(21) Appl. No.: 19/234,153

(22) Filed: Jun. 10, 2025

Related U.S. Application Data
(60) Provisional application No. 63/677,818, filed on Jul. 31, 2024.

(51) Int. Cl. H10B 12/00; H10D 30/62; H10D 62/13; H10D 62/60; H10D 62/832; H10D 62/834; H10D 64/01; H10D 64/23

(52) U.S. Cl. CPC H10B 12/36; H10B 12/056; H10B 12/50; H10D 30/6211; H10D 62/151; H10D 62/60; H10D 62/832; H10D 62/834; H10D 64/017; H10D 64/256

(57) ABSTRACT

Implementations described herein relate to various structures, integrated assemblies, and memory devices. In some implementations, an integrated assembly includes a first transistor structure for a first integrated circuit device. The first transistor structure includes a first source-drain region having a truncated elliptical shape. The integrated assembly includes a second transistor structure for a second integrated circuit device. The second transistor includes a second source-drain region having an approximately semi-elliptical shape.

### CROSS-REFERENCE TO RELATED APPLICATION

This Patent Application claims priority to U.S. Provisional Patent Application No. 63/677,818, filed on Jul. 31, 2024, entitled “SEMICONDUCTOR DEVICE WITH INDEPENDENT SOURCE-DRAIN REGION PROFILES FOR LOW VOLTAGE AND HIGH VOLTAGE FINFET TRANSISTORS,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor device having independent source-drain region profiles for low voltage and high voltage transistors.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 is an isometric view of an example implementation of a finFET structure described herein.

FIGS. 3A-3E are diagrammatic views of an example implementation described herein.

FIG. 4 is a diagrammatic view of example distal relationships between source-drain regions and gate structures described herein.

FIG. 5 is a diagrammatic view of example junction profiles associated with finFET structures described herein.

FIG. 6 is a flowchart of an example method of forming an integrated assembly or memory device having independent source-drain profiles.

FIGS. 7 includes diagrammatic views showing formation of finFET structures at example process stages of an example process of forming the finFET structures.

FIG. 8 is a diagrammatic view of an example memory device described herein.

### DETAILED DESCRIPTION

Fin channel field-effect transistor (finFET) technology is a cornerstone in the fabrication of modern semiconductor devices, particularly due to its enhanced performance in terms of on-state current (Ids) to off-state current (Idoff) ratio. This characteristic is particularly important in the logic industry, where power efficiency and high performance are required. However, as dynamic random access memory (DRAM) integrated circuit devices require higher supply voltages than those typically used in logic integrated circuit devices, the approach to finFET design must be adapted in order to cope with the distinct requirements. One significant issue that arises with the use of higher voltages in DRAM integrated circuit devices is the increase in gate-induced drain leakage (GIDL) and/or trap-assisted-tunneling (TAT) current, which can cause a significant increase in leakage current that impacts the reliability and stand-by power of the DRAM integrated circuit devices. As a result, finFET arrangements that are successful with logic integrated circuit devices prove to be suboptimal for DRAM integrated circuit devices, where GIDL and/or TAT currents become a limiting factor in a quality and/or a reliability of the DRAM integrated circuit devices. This discrepancy introduces a technical challenge when trying to incorporate finFETs into a semiconductor device including both logic and DRAM integrated circuit devices without compromising on the energy efficiency and longevity of the semiconductor device as a whole.

Some implementations described herein enable optimization of a semiconductor device including low voltage (LV) and high voltage (HV) integrated circuit devices by customizing profiles for source-drain regions of finFETs used by the LV and HV integrated circuit devices. In some implementations, a finFET for an LV integrated circuit device (e.g., a logic integrated circuit device) uses a source-drain region having a truncated elliptical shape and a relatively greater volume of semiconductive material, and a finFET for an HV integrated circuit device (e.g., a DRAM integrated circuit device) uses a source-drain region having a semi-elliptical shape and a relatively lesser volume of semiconductive material. Furthermore, a junction profile (e.g., a distribution of dopant concentrations) within the source-drain region of the finFET for the LV integrated circuit device may have a gradient that is greater (e.g., the junction profile is more abrupt) than a gradient of a junction profile within the source-drain region of the finFET for the HV integrated circuit device.

The customizations of the shapes and junction profiles enable the LV integrated circuit device to achieve an optimized drive current (higher I_{ds}) due to reduced access resistance and enhanced mobility through increased strain from the larger volume of semiconductive material. For the HV integrated circuit device, the approach mitigates GIDL or TAT currents by enabling a relaxed electric field effect resulting from the lesser volume of semiconductive material and the lesser gradient junction profile, which is essential in addressing leakage challenges in high voltage applications for DRAM integrated circuitry.

In this way, off-state leakage of the semiconductor device is reduced. By reducing the leakage current of the semiconductor device, an amount of resources used to support a market consuming the semiconductor device (e.g., raw materials, semiconductor manufacturing tools, labor, and/or computing resources) is reduced. Moreover, this technique facilitates performance optimization of finFETs across differing voltage requirements, simultaneously enhancing current drive capabilities in the LV integrated circuit device while preserving low leakage characteristics vital for HV integrated circuit device.

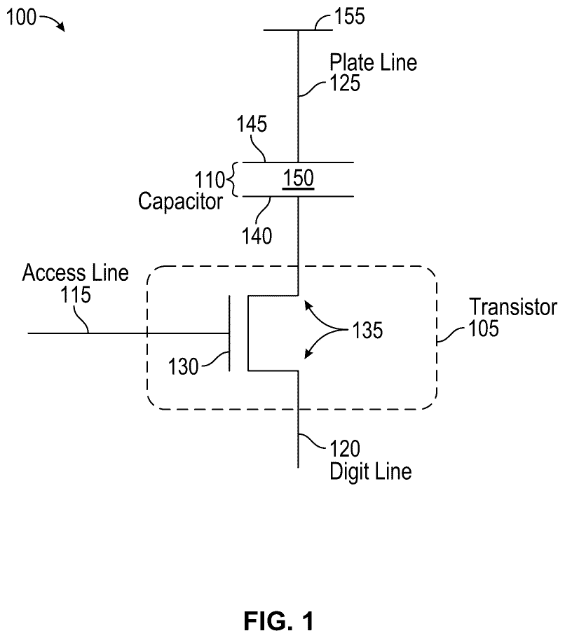

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor structure 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor structure 105 (sometimes called an access transistor) may include a gate structure 130 and source-drain regions 135. The capacitor 110 includes a bottom electrode 140 and a top electrode 145 separated by an insulator 150. In some implementations, the capacitor is a ferroelectric capacitor, and the insulator 150 is a ferroelectric insulator that comprises, consists of, or consists essentially of ferroelectric material. Alternatively, the capacitor may be a linear dielectric capacitor, and the insulator 150 may be a linear dielectric insulator that comprises, consists of, or consists essentially of linear dielectric material. Alternatively, the capacitor may be a paraelectric capacitor, and the insulator 150 may be a paraelectric insulator that comprises, consists of, or consists essentially of paraelectric material. When the access line 115 is activated (e.g., when a voltage is applied to the access line 115), the gate structure 130 coupled to the access line 115 may be activated. When the gate structure 130 is activated, the transistor structure 105 couples the digit line 120 to the bottom electrode 140 of the capacitor 110. A state of the memory cell 100 may then be written or read via the digit line 120.

The top electrode 145 of the capacitor 110 may be coupled to the plate line 125 and a cell plate 155. To write to (or program) the memory cell 100, the access line 115 may be activated, and a voltage may be applied across the capacitor 110 by controlling the voltage of the top electrode 145 (via the plate line 125 and/or the cell plate 155) and/or the bottom electrode 140 (via the digit line 120).

For a ferroelectric capacitor, the applied voltage creates an electric field, and the atoms in the ferroelectric material of the insulator 150 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 150 between the bottom electrode 140 and the top electrode 145). For example, a voltage of the cell plate 155 and the digit line 120 may be controlled. In some implementations, a negative polarity of the insulator 150 as compared to the cell plate 155 results in a logic “0” state being stored in the capacitor 110, and a positive polarity of the insulator 150 as compared to the cell plate 155 results in a logic “1” state being stored in the capacitor 110. For a linear dielectric capacitor or a paraelectric capacitor, the cell plate 155 may grounded, and the capacitor 110 may be charged by applying a voltage to the bottom electrode 140 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with regard to FIG. 1.

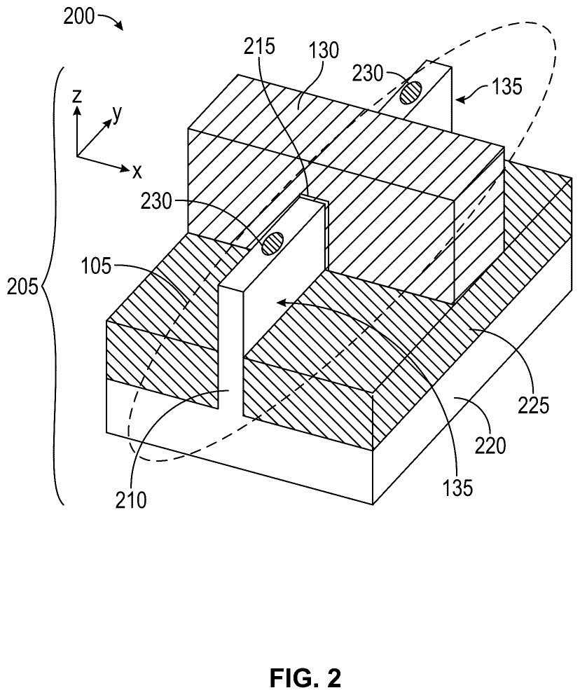

FIG. 2 is an isometric view of an example implementation 200 of a finFET structure 205 described herein. In some implementations, and as shown in FIG. 2, at least a portion of the finFET structure 205 corresponds to the transistor structure 105 of FIG. 1.

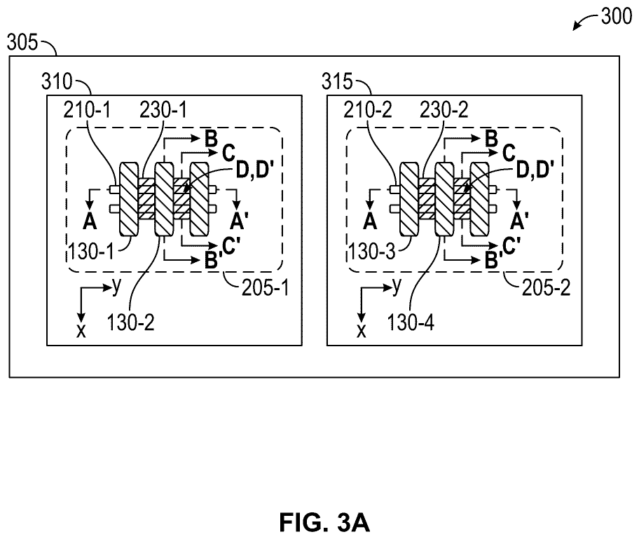

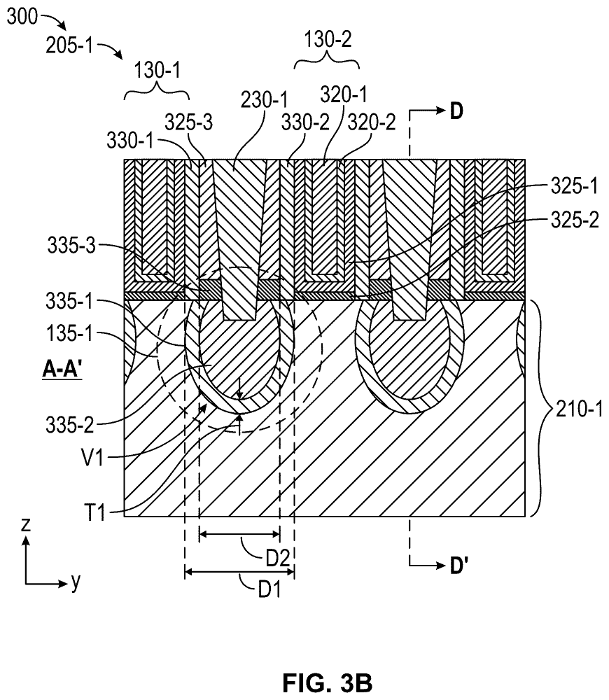

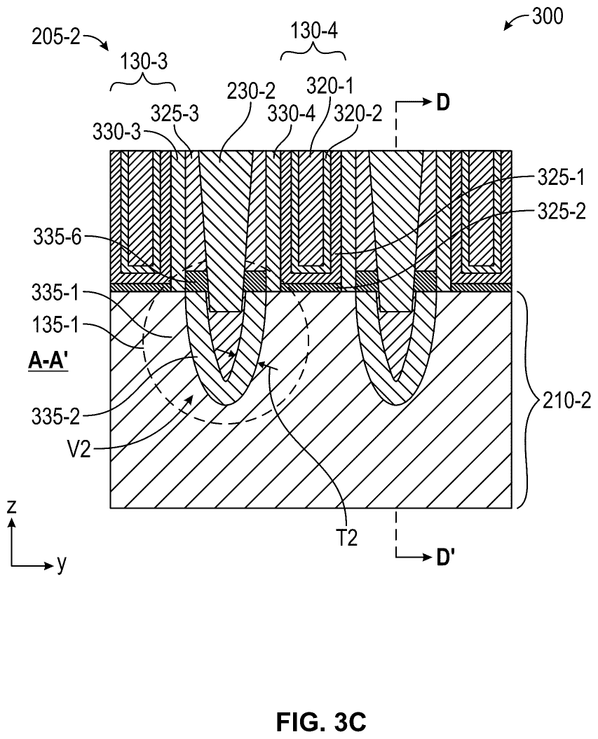

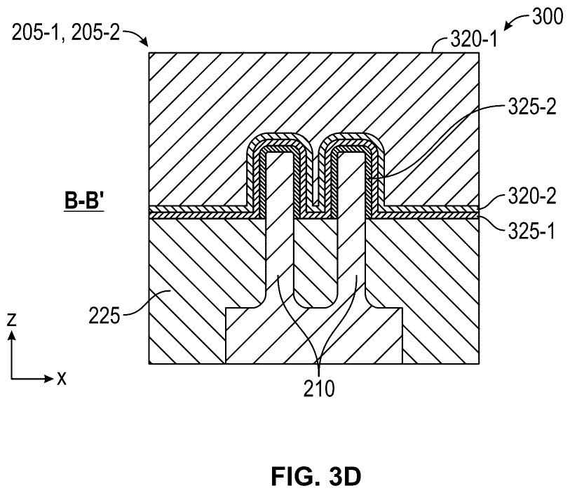

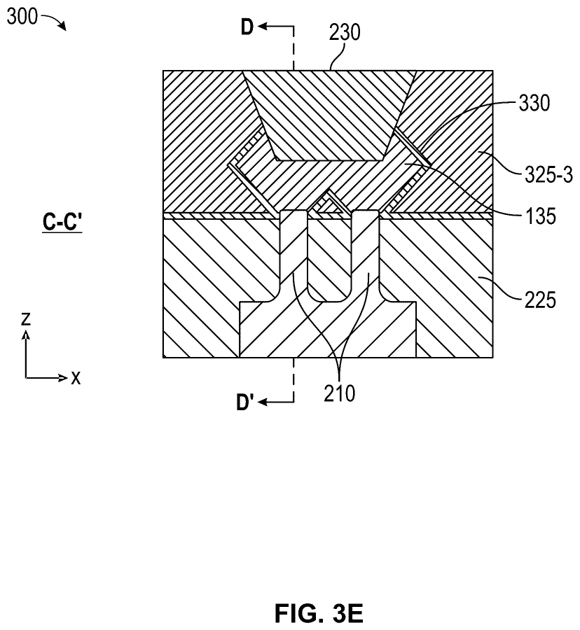

As shown in FIG. 2, the finFET structure 205 includes the gate structure 130 of FIG. 1. As described in greater detail in connection with FIGS. 3A-3E, the gate structure 130 may include layers of conductive materials and/or insulative (e.g., dielectric) materials. A conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. An insulative material may comprise, consist of, or consist essentially of silicon dioxide, hafnium oxide, and/or silicon nitride, among other examples.

As further shown in FIG. 2, the finFET structure 205 includes the source-drain regions 135 of FIG. 1. The source-drain regions 135 may be formed as part of a fin 210 that passes through the gate structure 130. In some implementations, and in addition to being used as part of an access transistor structure (e.g., the transistor structure 105 of FIG. 1), the finFET structure 205 including the source-drain regions 135 may be used in other transistor applications, such as a transistor that is used to access a word line driver, a transistor that is used as part of a switch or amplifier in a sense amplifier circuit, or a transistor included peripheral circuitry of a memory device, among other examples.

In some implementations, the source-drain regions 135 (and/or the fin 210) include one or more layers of a semiconductive material. A semiconductive material may comprise, consist of, or consist essentially of silicon (e.g., polycrystalline silicon), silicon germanium, silicon phosphide, or a type III-V element, material among other examples. Furthermore, and as described in greater detail in connection with FIGS. 3A-3E, the source-drain regions 135 may include multiple layers of semiconductive materials that are epitaxially grown and implanted with dopants (e.g., arsenic (As), phosphorous (Ph), or boron (B)) that alter an electrical behavior of the semiconductive materials.

In some implementations, and as shown in FIG. 2, a gate oxide 215 may surround a portion of the fin 210 passing through the gate structure 130 to electrically isolate the fin 210, reduce leakage within the transistor structure 105, and control a threshold voltage (Vₜₕ) performance of the transistor structure 105. The gate oxide 215 may include a high-k dielectric material that comprises, consists of, or consists essentially of silicon dioxide or hafnium oxide, among other examples.

In some implementations, and as shown in FIG. 2, the fin 210 extends from a substrate 220 and through an insulator 225. The substrate 220 may include a semiconductive material as described above, and the insulator 225 may include a layer of an insulative material as described above.

In some implementations, and as shown in FIG. 2, source-drain contacts 230 electrically couple to the fin 210 to inject current, collect current, bias the transistor structure 105, and/or apply a voltage to the transistor structure 105. The source-drain contacts 230 may include one or more layers of a conductive material, as described above.

As indicated above, FIG. 2 is provided as an example. Other examples may differ from what is described with regard to FIG. 2.

FIGS. 3A-3E are diagrammatic views of an example implementation 300 described herein. The implementation 300 may include variations of the finFET structure 205 described in connection with FIG. 2.

As shown in the plan view of FIG. 3A, a semiconductor device 305 includes an LV integrated circuit device 310 (e.g. logic integrated circuitry) and an HV integrated circuit device 315 (e.g., memory integrated circuitry). The semiconductor device 305 may be a system-on-chip (SoC) semiconductor device or an embedded DRAM (eDRAM) device, among other examples.

The LV integrated circuit device 310 may include the finFET structure 205-1 (e.g., a low voltage transistor) and the HV integrated circuit device 315 may include the finFET structure 205-2 (e.g., a high voltage transistor). Both the finFET structure 205-1 and the finFET structure 205-2 may include multiple fins 210, multiple gate structures 130, and multiple source-drain contacts 230 to enhance transistor performance. Section lines A-A′, B-B′, C-C′, and D-D′ shown in FIG. 3A are used to describe additional details of the finFET structures 205-1 and 205-2 in connection with FIGS. 3B-3E.

As shown in section view A-A′ of FIG. 3B, the finFET structure 205-1 (e.g., a low voltage transistor) may include two or more gate structures 130. For example, and as shown in FIG. 3B, the finFET structure 205-1 includes a gate structure 130-1 and a gate structure 130-2. Each of the gate structures 130-1 and 130-2 may include multiple conductive layers 320, including a conductive layer 320-1 (e.g., a tungsten layer) and a conductive layer 320-2 (e.g., a titanium nitride layer). One or more dielectric layers 325 may surround portions of the conductive layers 320, including a dielectric layer 325-1 (e.g., a hafnium oxide layer) and a dielectric layer 325-2 (e.g., a silicon dioxide layer).

In some implementations, spacers 330 (e.g., formed from a dielectric layer) may be along sidewalls of the gate structures 130. For example, a spacer 330-1 is along a sidewall of the gate structure 130-1 and a spacer 330-2 is along the sidewall of the gate 330-2. Furthermore, and as shown in FIG. 3B, surfaces of the spacer 330-1 and the spacer 330-2 may face each other. In other words, the surfaces of the spacer 330-1 and 330-2 may be “co-facing” surfaces.

As shown in FIG. 3B, a source-drain region 135-1 that penetrates into a fin 210-1 may be between the gate structures 130-1 and 130-2. The source-drain region 135-1 may be a multi-layer structure that includes multiple semiconductive layers 335, including a semiconductive layer 335-1 (e.g., an outer epitaxial layer), a semiconductive layer 335-2 (e.g., an inner epitaxial layer), and a semiconductive layer 335-3 (e.g., a capping epitaxial layer). As shown in FIG. 3B, the semiconductive layer 335-2 is conjoined with the semiconductive layer 335-1. Furthermore, the semiconductive layer 335-3 is conjoined with both the semiconductive layer 335-1 and the semiconductive layer 335-2. Each of the semiconductive layers 335-1 through 335-3 may include an epitaxially grown, semiconductive material such as silicon germanium, silicon phosphate, a type III-V element material, or another suitable semiconductive material, among other examples.

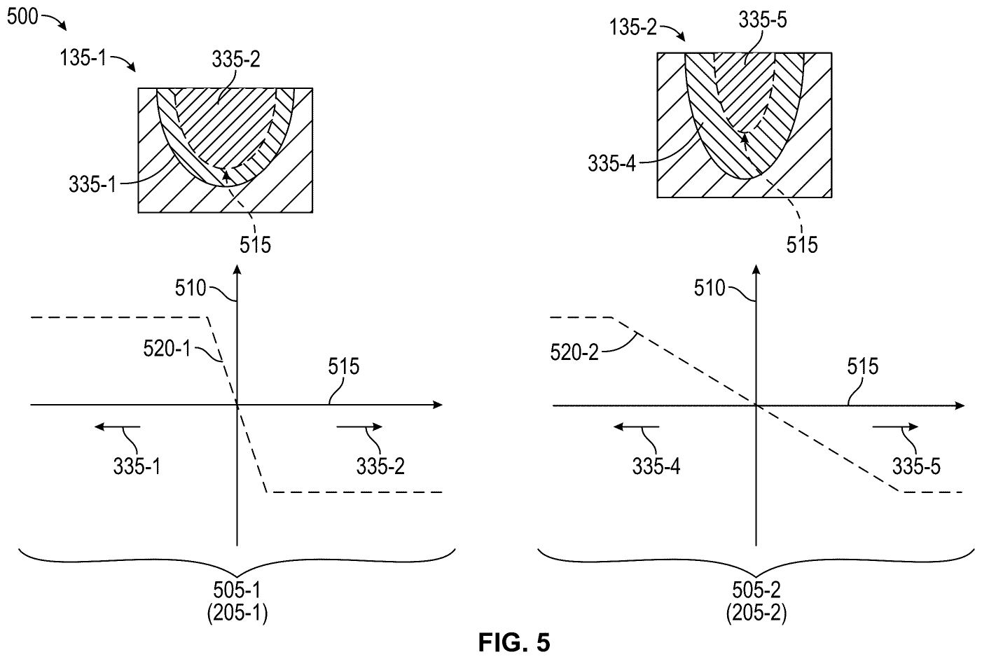

As shown in FIG. 3B, the semiconductive layer 335-1 has thickness T1. As described in greater detail in connection with FIG. 5, the thickness T1, in combination with concentrations of dopants within the semiconductive layers 335-1 through 335-3, may create a substantially abrupt junction profile that enables a reduced gate length by suppressing short-channel effects and reduces an access resistance within the finFET structure 205-1.

In some implementations, the finFET structure 205-1 is a p-channel metal oxide semiconductor (PMOS) structure. In such implementations, the semiconductive layers 335-1 through 335-3 may be silicon germanium (SiGe) or silicon (Si) that is doped with boron (B), among other examples. In some implementations, the finFET structure 205-1 is an n-channel metal oxide semiconductor (NMOS) structure. In such implementations, the semiconductive layers 335-1 through 335-3 may be silicon (Si) that is doped with arsenic (As) or phosphorous (P), among other examples.

As shown in FIG. 3B, and for an LV integrated circuit device (e.g., the LV integrated circuit device 310), the source-drain region 135-1 may have a truncated elliptical shape. As a result, a distance D1 between outer apexes of the source-drain region 135-1 may be greater than a distance D2 between the co-facing surfaces of the spacers 330-1 and 330-2. Further, the truncated elliptical shape may define a volume V1 of semiconductive materials within the source-drain region 135-1 that causes a higher strain in a channel region of the finFET structure 205-1 to increase a mobility of charge carriers within the channel region. The increased mobility in charge carriers, in combination with the reduced gate length and reduced access resistance caused by the abrupt junction profile, may make the finFET structure 205-1 suitable for use in the LV integrated circuit device.

As further shown in FIG. 3B, a source-drain contact 230-1 (e.g., formed from a conductive material such as tungsten) may penetrate into the source-drain region 135-1. In some implementations, a dielectric layer 325-3 (e.g., silicon dioxide) surrounds the source-drain contact 230.

As shown in section view A-A′ of FIG. 3C, the finFET structure 205-2 (e.g., a high voltage transistor) may include two or more gate structures 130. For example, and as shown in FIG. 3C, the finFET structure 205-2 includes a gate structure 130-3 and a gate structure 130-4. Each of the gate structures 130-3 and 130-4 may include multiple conductive layers 320, including the conductive layer 320-1 (e.g., a tungsten layer) and the conductive layer 320-2 (e.g., a titanium nitride layer). One or more dielectric layers 325 may surround portions of the conductive layers 320, including the dielectric layer 325-1 (e.g., a hafnium oxide layer) and the dielectric layer 325-2 (e.g., a silicon dioxide layer).

In some implementations, spacers 330 (e.g., formed from a dielectric material) may be along sidewalls of the gate structures 130. For example, a spacer 330-3 is along a sidewall of the gate structure 130-3 and a spacer 330-4 is along the sidewall of the gate 330-4. Further, and as shown in FIG. 3B, surfaces of the spacer 330-3 and the spacer 330-4 face each other. In other words, the surfaces of the spacer 330-3 and 330-4 may be “co-facing” surfaces.

As shown in FIG. 3C, a source-drain region 135-2 that penetrates into a fin 210-2 may be between the gate structures 130-3 and 130-4. The source-drain region 135-2 may be a multi-layer structure that includes a semiconductive layer 335-4 (e.g., an epitaxial layer), a semiconductive layer 335-5 (e.g., an inner epitaxial layer), and a semiconductive layer 335-6 (e.g., a capping epitaxial layer). As shown in FIG. 3C, the semiconductive layer 335-5 is conjoined with the semiconductive layer 335-4. Furthermore, the semiconductive layer 335-6 is conjoined with both the semiconductive layer 335-4 and the semiconductive layer 335-5. Each of the semiconductive layers 335-4 through 335-6 may include an epitaxially grown, semiconductive material such as silicon germanium, silicon phosphate, a type III-V element material, or another suitable semiconductive material, among other examples.

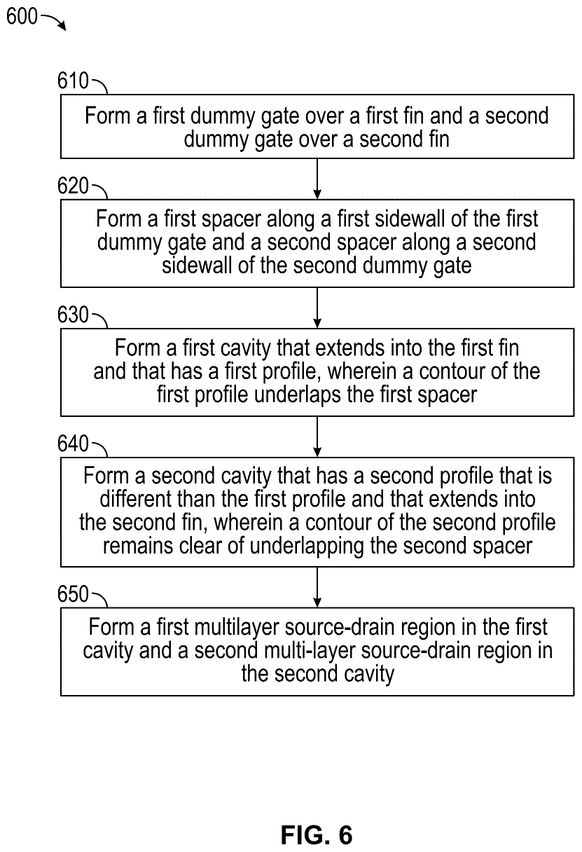

As shown in FIG. 3C, the semiconductive layer 335-4 has a thickness T2. In some implementations, the thickness T2 is greater than the thickness Tl of the semiconductive layer 335-1 described in connection with FIG. 3B. Further, and as described in greater detail below in connection with FIG. 6, the thickness T2, in combination with concentrations of dopants within the semiconductive layers 335-4 through 335-6, may create a graduated junction profile that increases an access resistance within the finFET structure 205-2.

In some implementations, the finFET structure 205-2 is a p-channel metal oxide semiconductor (PMOS) structure. In such implementations, the semiconductive layers 335-4 through 335-6 may be silicon germanium (SiGe) or silicon (Si) that is doped with boron (B), among other examples. In some implementations, the finFET structure 205-2 is an n-channel metal oxide semiconductor (NMOS) structure. In such implementations, the semiconductive layers 335-4 through 335-6 may be silicon (Si) that is doped with arsenic (As) or phosphorous (P), among other examples.

As shown in FIG. 3C, and for an HV integrated circuit device (e.g., the HV integrated circuit device 315), the source-drain region 135-2 may have an approximately semi-elliptical shape. As a result, a width W across the source-drain region 135-2 may decrease with an increase in depth of penetration of the source-drain region 135-2 into the fin 210-2. Further, the semi-elliptical shape may define a volume V2 of semiconductive materials within the source-drain region 135-2, where the volume V2 is less than the volume V1 of the source-drain region 135-1 as described in connection with FIG. 3B. The reduced volume, in combination with the graduated junction profile, may relax an electric field within the finFET structure 205-2 to reduce GIDL within the finFET structure 205-2 and make the finFET structure 205-2 suitable for use in a HV integrated circuit device.

As further shown in FIG. 3C, the source-drain contact 230-2 (e.g., formed from a conductive material such as tungsten) may penetrate into the source-drain region 135-2. In some implementations, the dielectric layer 325-3 (e.g., silicon dioxide) surrounds the source-drain contact 230-2.

Section view B-B′ of FIG. 3D shows additional details that apply to either of the finFET structure 205-1 (e.g., sectioned along the gate structure 130-2) or the finFET structure 205-2 (e.g., sectioned along the gate structure 130-4). As shown in FIG. 3D, the insulator 225 may surround bases of the fins 210 (e.g., the fin 210-1 or the fin 210-2). FIG. 3D further shows the conductive layer 320-1, the conductive layer 320-2, the dielectric layer 325-1, and the dielectric layer 325-2.

Section view C-C′ of FIG. 3E shows additional details that apply to either of the finFET structure 205-1 or the finFET structure 205-2 as sectioned along a source-drain contact 230. As shown in FIG. 3E, the insulator 225 may surround bases of the fins 210 (e.g., the fin 210-1 or the fin 210-2). The source-drain contact 230 (e.g., the source-drain contact 230-1 or the source-drain contact 230-2) penetrates into the source-drain region 135 (e.g., the source-drain region 135-1 or the source-drain region 135-2). FIG. 3E further shows a layer corresponding to the spacers 330 (e.g., the spacer 330-1, 330-2, 330-3, or 330-4) and the dielectric layer 325-3.

As indicated above, FIGS. 3A-3E are provided as one or more examples. Other examples may differ from what is described with regard to FIGS. 3A-3E.

As described in connection with FIGS. 1-3E, and some implementations, an integrated assembly (e.g., the semiconductor device 305) includes a first transistor structure (e.g., the finFET structure 205-1) for a first integrated circuit device (e.g., the LV integrated circuit device 310). The first transistor structure includes a first spacer (e.g., the spacer 330-1) along a first sidewall of a first gate structure (e.g., the gate structure 130-1) and a second spacer (e.g., the spacer 330-2) along a second sidewall of a second gate structure (e.g., the gate structure 130-2). The first transistor structure includes a first source-drain region (e.g., the source-drain region 135-1) having a truncated elliptical shape that is between the first spacer and the second spacer and that penetrates into a first fin (e.g., the fin 210-1) below the first spacer and the second spacer. The integrated assembly includes a second transistor structure (e.g., the finFET structure 205-1) for a second integrated circuit device (e.g., the HV integrated circuit device 315). The second transistor structure includes a third spacer (e.g., the spacer 330-3) along a third sidewall of a third gate structure (e.g. the gate structure 130-3) and a fourth spacer (e.g., the spacer 330-4) along a fourth sidewall of a fourth gate structure (e.g., the gate structure 130-4). The second source-transistor structure includes a second source-drain region (e.g., the source-drain region 135-2) having an approximately semi-elliptical shape that is between the third spacer and the fourth spacer and that penetrates into a second fin (e.g., the fin 210-2) below the third spacer and the fourth spacer.

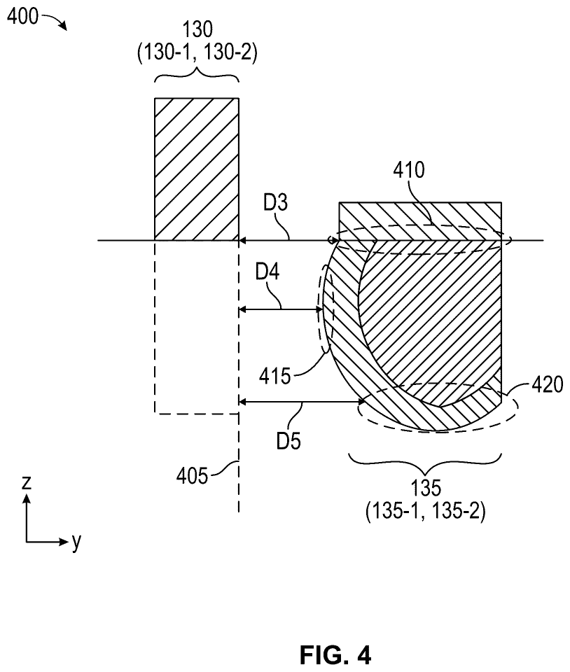

FIG. 4 is a diagrammatic view of example distal relationships 400 between source-drain regions (e.g., implementations of the source-drain region 135, including the source-drain region 135-1 or the source-drain region 135-2) and a gate structure (e.g., implementations of the gate structure 130, including the gate structure 130-1 or the gate structure 130-3) described herein.

As shown in FIG. 4, a first outer edge of a gate structure 130 may establish an approximately linear boundary 405 adjacent to a source-drain region 135. Distances between the approximately linear boundary 405 (e.g., proximities) and points along a first outer contour of the source-drain region 135 may be defined in the context of a distance D3 between the approximately linear boundary 405 and a surface region 410 of the source-drain region 135, a distance D4 between the approximately linear boundary 405 and a mid-region 415 of the source-drain region 135, and a distance D5 between the approximately linear boundary 405 and a tip region 420 of the source-drain region 135.

For the source-drain region 135-1 (e.g., a LV source-drain region having a truncated elliptical shape), the distance D4 may be less than D3. Additionally, or alternatively, the distance D5 may be greater than or equal to D3.

For the source-drain region 135-2 (e.g., a HV source-drain region having an approximately semi-elliptical shape), the distance D4 may be greater than D3, and the distance D5 may be greater than D4.

As indicated above, FIG. 4 is provided as one or more examples. Other examples may differ from what is described with regards to FIG. 4.

As described in connection with FIGS. 1-4, and in some implementations, an apparatus (e.g., the semiconductor device 305) includes a first integrated circuit device (e.g., the LV integrated circuit device 310) including a first finFET structure (e.g., the finFET structure 205-1). The first finFET structure includes a first gate structure (e.g., the gate structure 130-1) having a first outer edge defining a first approximately linear boundary (e.g., the approximately linear boundary 405) and a first source-drain region (e.g., the source-drain region 135-1). The first source-drain region includes a first surface region (e.g., the surface region 410) located a first distance (e.g., the distance D3) from the first approximately linear boundary and a first mid-region (e.g., the mid-region 415) located a second distance (e.g., the distance D4) from the first approximately linear boundary, where the second distance is less than the first distance. The first source-drain region further includes a first tip region (e.g., the tip region 420) located a third distance (e.g., the distance D5) from the first approximately lincar boundary, where the third distance is less than the second distance, and where the third distance is greater than or equal to the first distance. The apparatus further includes a second integrated circuit device (e.g., the HV integrated circuit device 315) including a second finFET structure (e.g., the finFET structure 205-2). The second finFET structure includes a second gate structure (e.g., the gate structure 130-2) having a second outer edge defining a second approximately linear boundary (e.g., the approximately linear boundary 405) and a second source-drain region (e.g., the source-drain region 135-2). The second source-drain region includes a second surface region (e.g., the surface region 410) located a fourth distance (e.g., the distance D3) from the second approximately linear boundary and a second mid-region (e.g., the mid-region 415) located a fifth distance (e.g., the distance D4) from the second approximately linear boundary, where the fifth distance is greater less than fourth distance. The second source-drain region further includes a second tip region (e.g., the tip region 420) located a sixth distance (e.g., the distance D5) from the second approximately linear boundary, wherein the sixth distance is greater than the fifth distance.

FIG. 5 is a diagrammatic view of example junction profiles 500 associated with finFET structures (e.g., the finFET structure 205-1 and the finFET structure 205-2) described herein. “Junction profile” may refer to a spatial distribution of dopant concentrations within the different regions (source, drain, and channel) of the finFET structures at interfaces where the differently doped semiconductive regions mect. By affecting the electric field distribution and potential barriers within a semiconductor device including the transistor, the junction profiles 500 may determine electrical characteristics of the FinFET structures (e.g., transistors), including the threshold voltage (Vₜₕ).

In FIG. 5, junction profiles 500 are shown in graphs plotting a concentration of dopants 510 (e.g., atoms per cubic centimeter) versus a location 515 relative to an interface between differently doped semiconductive regions. A rate of variation in concentrations may correspond to a slope 520 included in the junction profiles 500.

As shown in FIG. 5, the junction profile 505-1 (e.g., a junction profile for an LV transistor) includes a slope 520-1 that is abrupt. The slope 520-1 (e.g., corresponding to a steep dopant gradient) can lead to a higher electric field at the interface, potentially increasing source/drain to substrate leakage due to an increased probability of band-to-band and/or trap-assisted tunneling of carriers.

Forming the finFET structure 205-1 (e.g., a transistor) with the junction profile 505-1 may include a significant variation of concentrations of dopants within a source-drain region that cause the slope 520-1 to be abrupt. For example, and as part of the source-drain region 135-1, a concentration of a dopant in an outer semiconductive layer (e.g., the semiconductive layer 335-1) may be significantly less than a concentration of the dopant in an inner semiconductive layer (e.g., the semiconductive layer 335-2).

As further shown in FIG. 5, a slope 520-2 of the junction profile 505-2 (e.g., a junction profile for a HV transistor) is gradual. The junction profile 505-2 may result in a lower electric field at the junction, reducing leakage current with a reduced probability of band-to-band and/or trap assisted tunneling of carriers.

Forming the finFET structure 205-1 (e.g., a transistor) with the junction profile 505-2 may include a slight variation of concentrations of dopants within a source-drain region that cause the slope 520-2 to be graduated. For example, and as part of the source-drain region 135-2, a concentration of a dopant in an outer semiconductive layer (e.g., the semiconductive layer 335-4) may be slightly less than a concentration of the dopant in an inner semiconductive layer (e.g., the semiconductive layer 335-5).

As indicated above, FIG. 5 is provided as one or more examples. Other examples may differ from what is described with regard to FIG. 5.

FIG. 6 is a flowchart of an example method 600 of forming an integrated assembly or memory device having independent source-drain profiles. In some implementations, one or more process blocks of FIG. 6 may be performed by various semiconductor manufacturing equipment.

As shown in FIG. 6, the method 600 may include forming a first dummy gate over a first fin (e.g., the fin 210-1) and a second dummy gate over a second fin (e.g., the fin 210-2) (block 610). As further shown in FIG. 6, the method 600 may include forming a first spacer (e.g., the spacer 330-1) along a first sidewall of the first dummy gate and a second spacer (e.g., the spacer 330-3) along a second sidewall of the second dummy gate (block 620). As further shown in FIG. 6, the method 600 may include forming a first cavity that penetrates into the first fin and that has a first profile, wherein a contour of the first profile underlaps the first spacer (block 630). As further shown in FIG. 6, the method 600 may include forming a second cavity that has a second profile that is different than the first profile and that penetrates into the second fin, wherein a contour of the second profile remains clear of underlapping the second spacer (block 640). As further shown in FIG. 6, the method 600 may include forming a first multi-layer source-drain region (e.g., the source-drain region 135-1) in the first cavity and a second multi-layer source-drain region (e.g., the source-drain region 135-2) in the second cavity (block 650).

The method 600 may include additional aspects, such as any single aspect or any combination of aspects described below and/or in connection with one or more other methods described elsewhere herein.

In a first aspect, forming the first cavity that has the first profile includes forming a cavity having a truncated elliptical shape.

In a second aspect, alone or in combination with the first aspect, forming the second cavity that has the second profile includes forming a cavity having an approximately semi-elliptical shape.

In a third aspect, alone or in combination with one or more of the first and second aspects, forming the first cavity includes removing a first portion of the first fin using an anisotropic etch operation, and removing a second portion of the first fin using an isotropic etch operation.

In a fourth aspect, alone or in combination with one or more of the first through third aspects, forming the second cavity includes removing a portion of the second fin using an anisotropic etch operation.

In a fifth aspect, alone or in combination with one or more of the first through fourth aspects, forming the first multi-layer source-drain region and the second multi-layer source-drain region includes forming the first multi-layer source-drain region or forming the second multi-layer source-drain region using a series of epitaxial growth operations.

In a sixth aspect, alone or in combination with one or more of the first through fifth aspects, the method 600 includes replacing the first dummy gate with a first gate structure (e.g., the gate structure 130-1) to form a first transistor structure (e.g., the finFET transistor structure 205-1) having a first threshold voltage, and replacing the second dummy gate with a second gate structure (e.g., the gate structure 130-2) to form a second transistor structure (e.g., the finFET transistor structure 205-2) having a second threshold voltage that is greater than the first threshold voltage.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the finFET structures 205-1 and 205-2, an integrated assembly (e.g., the semiconductor device 305) that includes the finFET structures 205-1 and 205-2, any part described herein of the finFET structures 205-1 and 205-2, and/or any part described herein of an integrated assembly that includes the structure finFET structures 205-1 and 205-2. For example, the method 600 may include forming one or more of the LV integrated circuit device 310, the HV integrated circuit device 315, the source-drain region 135-1, or the source-drain region 135-2.

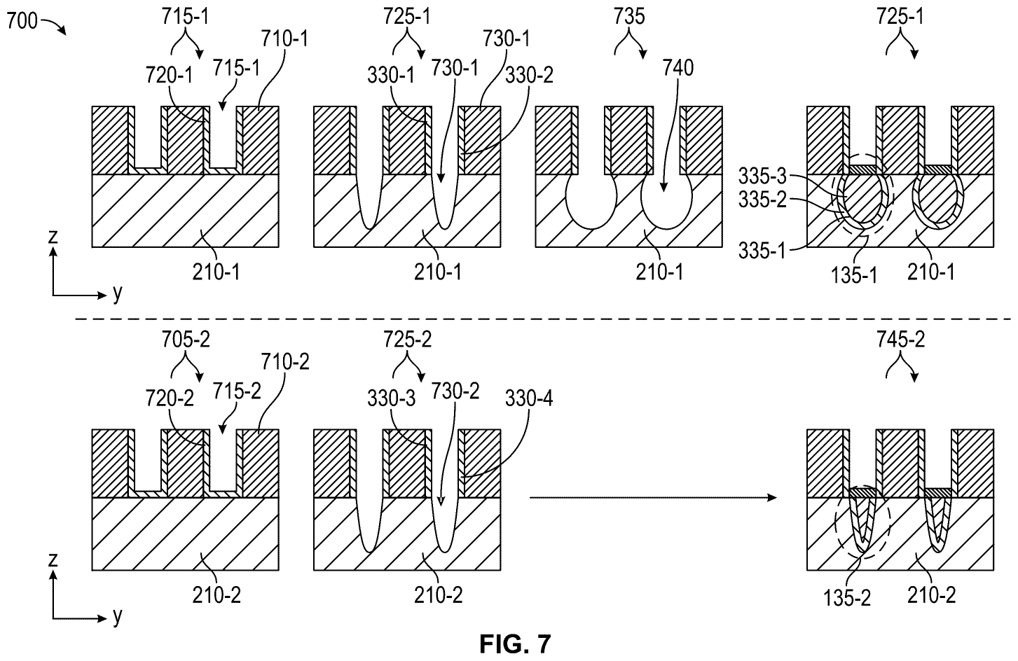

FIG. 7 includes diagrammatic views showing formation of finFET structures (e.g., the finFET structure 205-1 and the finFET structure 205-2) at example process stages of an example process of forming the finFET structures. In some implementations, the example process described below in connection with FIG. 7 may correspond to the method 600 and/or one or more blocks of the method 600. However, the process described below is an example, and other example processes may be used to form the finFET structures, an integrated assembly (e.g., the semiconductor device 305) that includes finFET structures, and/or one or more parts of the finFET structures (e.g., the source-drain region 135-1 or the source-drain region 135-2) and/or the integrated assembly.

As shown in FIG. 7, the series of operations 700 includes operations 705-1 and 705-2. As part of operation 705-1, the fin 210-1 is received with dummy gate structures 710-1 over the fin 210-1, where cavities 715-1 may separate and/or be between the dummy gate structures 710-1. Further, and as part of operation 705-1, a dielectric layer 720-1 may be formed along contours of the cavities 715-1. The dielectric layer 720-1 may be an electrical insulator and may comprise, consist of, or consist essentially of insulative material. The insulative material may comprise, consist of, or consist essentially of silicon dioxide and/or silicon nitride, among other examples. As part of operation 705-2, the fin 210-2 is received with dummy gate structures 710-2 over the fin 210-2, where cavities 715-2 may separate and/or be between the dummy gate structures 710-2. Further, and as part of operation 705-2, a dielectric layer 720-2 may be formed along contours of the cavities 715-2. The dielectric layer 720-2 may be an electrical insulator and may comprise, consist of, or consist essentially of insulative material. The insulative material may comprise, consist of, or consist essentially of silicon dioxide and/or silicon nitride, among other examples.

In some implementations, one or more aspects of the operations 705-1 and 705-2 are performed simultaneously. As an example, forming the dielectric layers 720-1 and 720-2 may occur during a deposition operation that simultaneously deposits the dielectric layers 720-1 along the contours of the cavities 715-1 and the dielectric layers 720-2 along the contours of the cavities 720-2. In such implementations, the dielectric layers 720-1 and 720-2 may have a same material and a same approximate thickness.

Alternatively, and in some implementations, one or more aspects of the operations 705-1 and 705-2 are performed separately. As an example, a first mask may be used to mask the cavities 715-2 during a first deposition operation that deposits the dielectric layers 720-1 along the contours of the cavities 715-1, and a second mask may be used to mask the cavities 715-1 during a second deposition operation that deposits the dielectric layers 720-2 along the contours of the cavities 720-2. In such implementations, the dielectric layers 720-1 and 720-2 may have different materials and/or different thicknesses.

As further shown in FIG. 7, the series of operation 700 includes operations 725-1 and 725-2. Operation 725-1 may include removing (e.g., etching) portions of the dielectric layer 720-1 to form the spacers 330-1 and 330-2. In some implementations, one or more masks may be used to remove the portions of the dielectric layer 720-1 to form the spacers 330-1 and 330-2. For example, one or more masks may be deposited and/or patterned on exposed ends of the dielectric layer 720-1 and the dummy gates 710-1 prior to removing the portions to form the spacers 330-1 and 330-2.

Operation 725-1 may further include removing portions of the fin 210-1 to form approximately semi-elliptical cavities 730-1 that penetrate into the fin 210-1. In some implementations, one or more masks may be used to remove the portions of the fin 210-1 to form the cavities 730-1. As an example, one or more masks may be deposited and/or patterned on the spacers 330-1 and 330-2 and the dummy gates 710-1 prior to removing the portions to form the cavities 730-1. In some implementations, removing the portions of the fin 210-1 includes using an anisotropic dry etch operation to form the cavities 730-1, where the cavities 730-1 have an approximately semi-elliptical shape.

Operation 725-2 may include removing (e.g., etching) portions of the dielectric layer 720-2 to form the spacers 330-3 and 330-4. In some implementations, one or more masks may be used to remove the portions of the dielectric layer 720-2 to form the spacers 330-3 and 330-4. For example, one or more masks may be deposited and/or patterned on exposed ends of the dielectric layer 720-2 and the dummy gates 710-2 prior to removing the portions to form the spacers 330-3 and 330-4.

Operation 725-2 may further include removing (e.g., etching) portions of the fin 210-2 to form approximately semi-elliptical cavities 730-2 that penetrate into the fin 210-2. In some implementations, one or more masks may be used to remove the portions of the fin 210-2 to form the cavities 730-2. As an example, one or more masks may be deposited and/or patterned on the spacers 330-3 and 330-4 and the dummy gates 710-2 prior to removing the portions to form the cavities 730-2. In some implementations, removing the portions of the fin 210-2 includes using an anisotropic dry etch operation to form the cavities 730-2, where the cavities 730-2 have an approximately semi-elliptical shape.

In some implementations, one or more aspects of the operations 725-1 and 725-2 are performed simultaneously. As an example, forming the cavities 730-1 and 730-2 may be performed by masking and etching operations that simultaneously form the cavities 730-1 in the fin 210-1 and the cavities 730-2 in the fin 210-2. In such implementations, the cavities 730-1 and 730-2 may have a same approximate curvature and a same approximate depth.

Alternatively, and in some implementations, one or more aspects of the operations 725-1 and 725-2 are performed separately. As an example, a first mask may be used to mask the fin 210-1, the dummy gates 710-1, the spacers 330-1, and the spacers 330-2 during a first etching operation that forms the cavities 730-2 in the fin 210-2, and a second mask may be used to mask the fin 210-2, the dummy gates 710-2, the spacers 330-3, and the spacers 330-4 during a second etching operation that forms the cavities 730-2 in the fin 210-2. In such implementations, the cavities 730-1 and 730-2 may have different curvatures and/or different depths.

As shown in FIG. 7, the series of operations 700 further includes operation 735. Operation 735 may include removing (e.g., etching) additional portions of fin 210-1 within the cavities 730-1 to form the cavities 740. In some implementations, one or more masks may be used to remove the additional portions of the fin 210-1 to form the cavities 740. For example, one or more masks may be deposited and/or patterned on the spacers 330-1, the spacers 330-2, and the dummy gates 710-1 prior to removing the additional portions of the fin 210-1 to form the cavities 740. In some implementations. removing the portions of the fin 210-2 includes using an isotropic dry etch operation to form the cavities 740, where the cavities 740 have a truncated elliptical shape.

In some implementations, and during the operation 735, one or more masks may be used to mask the cavities 730-2, the fins 710-2, and the spacers 330-3 and 330-4 to preserve a shape of the cavities 730-2.

As shown in FIG. 7, the series of operations 700 includes operations 745-1 and 745-2. As part of the operation 745-1, the source-drain region 135-1 may be formed by a series of deposition operations that epitaxially grow the semiconductive layers 335-1, 335-2, and 335-3. In some implementations, and after formation of each of the semiconductive layers 335-1, 335-2, and 335-3, an implant operation may implant impurities (e.g., implant dopants) into each of semiconductive layers 334-1, 335-2, and 335-3 as part of forming a junction profile (e.g., the junction profile 505-1). Alternatively, formation of the semiconductive layers 335-1, 335-2, and 335-3 may include a series of deposition operations that epitaxially grow the semiconductive layers 335-1, 335-2, and 335-3 in situ with dopants that form the junction profile.

As part of the operation 745-2, the source-drain region 135-2 may be formed by a series of deposition operations that epitaxially grow the semiconductive layers 335-4, 335-5, and 335-6. In some implementations, and after formation of each of the semiconductive layers 335-4, 335-5, and 335-6, an implant operation may implant impurities (e.g., implant dopants) into each of semiconductive layers 334-4, 335-5, and 335-6 as part of forming a junction profile (e.g., the junction profile 505-2). Alternatively, formation of the semiconductive layers 335-4, 335-5, and 335-6 may include a series of deposition operations that epitaxially grow the semiconductive layers 335-4, 335-5, and 335-6 in situ with dopants that form the junction profile.

In some implementations, the operations 745-1 and 745-2 are performed separately. For example, and in some implementations, a mask may be used to mask the dummy gates 710-2, the spacers 330-3 and 330-4, and the cavities 730-2 during formation (and/or implanting) of the semiconductive layers 335-1, 335-2, and 335-4. Alternatively, and in some implementations, a mask may be used to mask the dummy gates 710-1, the spacers 330-1 and 330-2, and the cavities 730-1 during formation (and/or implanting) of the semiconductive layers 335-4, 335-5, and 335-7.

In some implementations, the series of operations 700 may be extended to include additional removal operations (e.g. etching operations) and formation operations (e.g. deposition operations) that replace the dummy gates 710-1 and the dummy gates 710-2 with gate structures (e.g., the gate structures 130).

As indicated above, the process steps described in connection with FIG. 7 are provided as examples. Other examples may differ from what is described with respect to FIG. 7. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

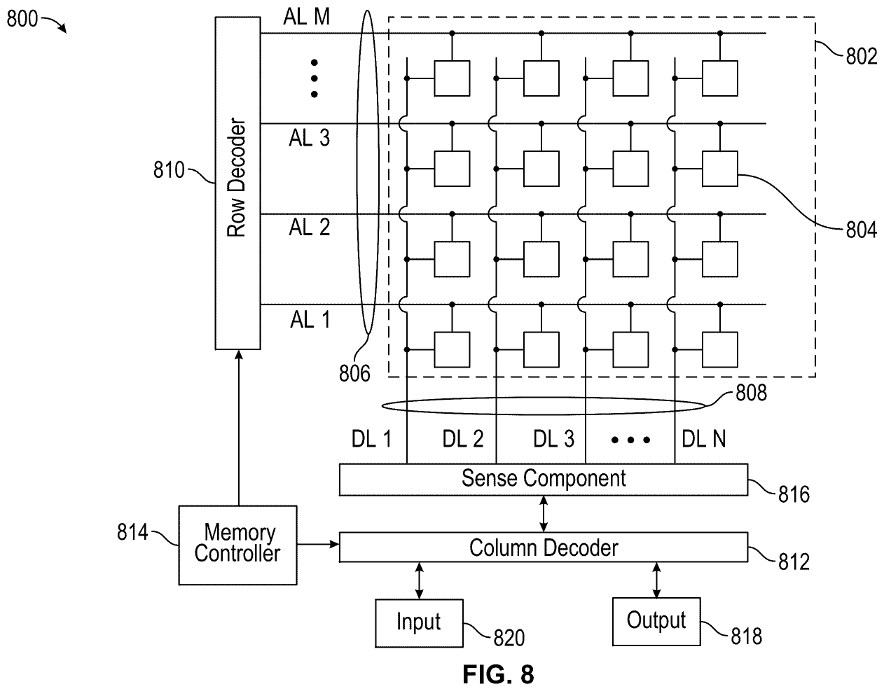

FIG. 8 is a diagrammatic view of an example memory device 800 described herein. The memory device 800 may include a memory array 802 that includes multiple memory cells 804. A memory cell 804 is programmable or configurable into a data state of multiple data states (e.g., two or more data states). For example, a memory cell 804 may be set to a particular data state at a particular time, and the memory cell 804 may be set to another data state at another time. A data state may correspond to a value stored by the memory cell 804. The value may be a binary value, such as a binary 0 or a binary 1, or may be a fractional value, such as 0.5, 1.5, or the like. A memory cell 804 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 804 by activating or selecting the appropriate access line 806 (shown as access lines AL 1 through AL M) and digit line 808 (shown as digit lines DL 1 through DL N). An access line 806 may also be referred to as a “row line” or a “word line,” and a digit line 808 may also be referred to a “column line” or a “bit line.” Activating or selecting an access line 806 or a digit line 808 may include applying a voltage to the respective line. An access line 806 and/or a digit line 808 may comprise, consist of, or consist essentially of a conductive material, such as a metal (e.g., copper, aluminum, gold, titanium, or tungsten) and/or a metal alloy, among other examples. In FIG. 8, cach row of memory cells 804 is connected to a single access line 806, and each column of memory cells 804 is connected to a single digit line 808. By activating one access line 806 and one digit line 808 (e.g., applying a voltage to the access line 806 and digit line 808), a single memory cell 804 may be accessed at (e.g., is accessible via) the intersection of the access line 806 and the digit line 808. The intersection of the access line 806 and the digit line 808 may be called an “address” of a memory cell 804.

In some implementations, the logic storing device of a memory cell 804, such as a capacitor, may be electrically isolated from a corresponding digit line 808 by a selection component, such as a transistor. The access line 806 may be connected to and may control the selection component. For example, the selection component may be a transistor, and the access line 806 may be connected to the gate of the transistor. Activating the access line 806 results in an electrical connection or closed circuit between the capacitor of a memory cell 804 and a corresponding digit line 808. The digit line 808 may then be accessed (e.g., is accessible) to either read from or write to the memory cell 804.

A row decoder 810 and a column decoder 812 may control access to memory cells 804. For example, the row decoder 810 may receive a row address from a memory controller 814 and may activate the appropriate access line 806 based on the received row address. Similarly, the column decoder 812 may receive a column address from the memory controller 814 and may activate the appropriate digit line 808 based on the column address.

Upon accessing a memory cell 804, the memory cell 804 may be read (e.g., sensed) by a sense component 816 to determine the stored data state of the memory cell 804. For example, after accessing the memory cell 804, the capacitor of the memory cell 804 may discharge onto its corresponding digit line 808. Discharging the capacitor may be based on biasing, or applying a voltage, to the capacitor. The discharging may induce a change in the voltage of the digit line 808, which the sense component 816 may compare to a reference voltage (not shown) to determine the stored data state of the memory cell 804. For example, if the digit line 808 has a higher voltage than the reference voltage, then the sense component 816 may determine that the stored data state of the memory cell 804 corresponds to a first value, such as a binary 1. Conversely, if the digit line 808 has a lower voltage than the reference voltage, then the sense component 816 may determine that the stored data state of the memory cell 804 corresponds to a second value, such as a binary 0. The detected data state of the memory cell 804 may then be output (e.g., via the column decoder 812) to an output component 818 (e.g., a data buffer). A memory cell 804 may be written (e.g., set) by activating the appropriate access line 806 and digit line 808. The column decoder 812 may receive data, such as input from input component 820, to be written to one or more memory cells 804. A memory cell 804 may be written by applying a voltage across the capacitor of the memory cell 804.

The memory controller 814 may control the operation (e.g., read, write, re-write, refresh, and/or recovery) of the memory cells 804 via the row decoder 810, the column decoder 812, and/or the sense component 816. The memory controller 814 may generate row address signals and column address signals to activate the desired access line 806 and digit line 808. The memory controller 814 may also generate and control various voltages used during the operation of the memory array 802.

In some implementations, the memory device 800 includes the finFET structure 205-1 and/or an integrated assembly that includes the finFET structure 205-1 (e.g., the finFET structure 205-1 including the source-drain region 135-1). For example, the memory array 802 may include the finFET structure 205-1 and/or an integrated assembly that includes the finFET structure 205-1. In some implementations, the memory device 800 may be part of a semiconductor device including a logic device Additionally, or alternatively, the memory cell 804 may include a memory cell described elsewhere herein.

As indicated above, FIG. 8 is provided as an example. Other examples may differ from what is described with respect to FIG. 8.

In some implementations, an integrated assembly includes a first transistor structure for a first integrated circuit device, comprising: a first spacer along a first sidewall of a first gate structure; a second spacer along a second sidewall of a second gate structure; a first source-drain region having a truncated elliptical shape that is between the first spacer and the second spacer and that penetrates into a first fin below the first spacer and the second spacer; and a second transistor structure for a second integrated circuit device, comprising: a third spacer along a third sidewall of a third gate structure; a fourth spacer along a fourth sidewall of a fourth gate structure; and a second source-drain region having an approximately semi-elliptical shape that is between the third spacer and the fourth spacer and that penetrates into a second fin below the third spacer and the fourth spacer.

In some implementations, an apparatus includes a first integrated circuit device, comprising; a first fin field effect transistor structure, comprising: a first gate structure having an outer edge defining a first approximately linear boundary; and a first source-drain region, comprising: a first surface region located a first distance from the first approximately linear boundary; and a first mid-region located a second distance from the first approximately linear boundary, wherein the second distance is less than the first distance; and a first tip region located a third distance from the first approximately linear boundary, wherein the third distance is less than the second distance, and wherein the third distance is greater than equal to the first distance; and a second integrated circuit device, comprising: a second fin field effect transistor structure, comprising: a second gate structure having a second outer edge defining a second approximately linear boundary; and a second source-drain region, comprising: a second surface region located a fourth distance from the second approximately linear boundary; and a second mid-region located a fifth distance from the second approximately linear boundary, wherein the fifth distance is greater less than fourth distance; and a second tip region located a sixth distance from the second approximately linear boundary, wherein the sixth distances is greater than the fifth distance.

In some implementations, a method includes forming a first dummy gate over a first fin and a second dummy gate over a second fin; forming a first spacer along a first sidewall of the first dummy gate and a second spacer along a second sidewall of the second dummy gate; forming a first cavity that penetrates into the first fin and that has a first profile, wherein a contour of the first profile underlaps the first spacer; forming a second cavity that has a second profile that is different than the first profile and that penetrates into the second fin, wherein a contour of the second profile remains clear of underlapping the second spacer; and forming a first multi-layer source-drain region in the first cavity and a second multi-layer source-drain region in the second cavity.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for case of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b +b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first transistor structure for a first integrated circuit device, comprising:
a first spacer along a first sidewall of a first gate structure;
a second spacer along a second sidewall of a second gate structure;
a first source-drain region having a truncated elliptical shape that is between the first spacer and the second spacer and that penetrates into a first fin below the first spacer and the second spacer; and
a second transistor structure for a second integrated circuit device, comprising:
a third spacer along a third sidewall of a third gate structure;
a fourth spacer along a fourth sidewall of a fourth gate structure; and
a second source-drain region having an approximately semi-elliptical shape that is between the third spacer and the fourth spacer and that penetrates into a second fin below the third spacer and the fourth spacer.

2. The integrated assembly of claim 1, wherein a first distance between outer apexes of the first source-drain region is greater than a second distance between co-facing surfaces of the first spacer and the second spacer.

3. The integrated assembly of claim 1, where a width of the second source-drain region decreases with an increase in a depth of penetration of the second source-drain region into the second fin.

4. The integrated assembly of claim 1, wherein the first source-drain region comprises a first multi-layer structure, and wherein the second source-drain region comprises a second multi-layer structure.

5. The integrated assembly of claim 4, wherein the first source-drain region comprises a first outer semiconductive layer having a first thickness, and wherein the second source-drain region comprises a second outer semiconductive layer having a second thickness that is greater than the first thickness.

6. The integrated assembly of claim 4, wherein the second source-drain region comprises:
a first outer semiconductive layer doped with a dopant at a first concentration, and
an inner semiconductive layer doped with the dopant at a second concentration that is greater than the first concentration.

7. The integrated assembly of claim 6, wherein the dopant comprises:
arsenic,
phosphorous, or
boron.

8. The integrated assembly of claim 1, wherein at least one of the first source-drain region or the second source-drain region comprises at least one layer of:
silicon germanium, or
silicon phosphorous.

9. An apparatus, comprising:
a first integrated circuit device, comprising;
a first fin field effect transistor structure, comprising:
a first gate structure having an outer edge defining a first approximately linear boundary; and
a first source-drain region, comprising:
a first surface region located a first distance from the first approximately linear boundary; and
a first mid-region located a second distance from the first approximately linear boundary,
wherein the second distance is less than the first distance; and
a first tip region located a third distance from the first approximately linear boundary,
wherein the third distance is greater than or equal to the first distance; and
a second integrated circuit device, comprising:
a second fin field effect transistor structure, comprising:
a second gate structure having a second outer edge defining a second approximately linear boundary; and
a second source-drain region, comprising:
a second surface region located a fourth distance from the second approximately linear boundary; and
a second mid-region located a fifth distance from the second approximately linear boundary,
wherein the fifth distance is greater less than fourth distance; and
a second tip region located a sixth distance from the second approximately linear boundary,
wherein the sixth distance is greater than the fifth distance.

10. The apparatus of claim 9, wherein the first source-drain region or the second source-drain region comprises:
a first outer epitaxial layer;
an inner epitaxial layer conjoined with the outer epitaxial layer; and
a capping epitaxial layer conjoined with the outer epitaxial layer and the inner epitaxial layer.

11. The apparatus of claim 10, wherein the first integrated circuit device comprises logic integrated circuity, and
wherein the second integrated circuit device comprises:
memory integrated circuitry.

12. The apparatus of claim 9, wherein a first gradient of a first junction profile of the first fin field effect transistor structure is greater than a second gradient of a second junction profile of the second fin field effect transistor structure.

13. The apparatus of claim 9, wherein a first volume of the first source-drain region is greater than a second volume of the second source-drain region.

14. A method, comprising:
forming a first dummy gate over a first fin and a second dummy gate over a second fin;
forming a first spacer along a first sidewall of the first dummy gate and a second spacer along a second sidewall of the second dummy gate;
forming a first cavity that penetrates into the first fin and that has a first profile,
wherein a contour of the first profile underlaps the first spacer;
forming a second cavity that has a second profile that is different than the first profile and that penetrates into the second fin,
wherein a contour of the second profile remains clear of underlapping the second spacer; and
forming a first multi-layer source-drain region in the first cavity and a second multi-layer source-drain region in the second cavity.

15. The method of claim 14, wherein forming the first cavity that has the first profile includes:
forming a cavity having a truncated elliptical shape.

16. The method of claim 14, wherein forming the second cavity that has the second profile includes:
forming a cavity having an approximately semi-elliptical shape.

17. The method of claim 14, wherein forming the first cavity includes:
removing a first portion of the first fin using an anisotropic etch operation, and
removing a second portion of the first fin using an isotropic etch operation.

18. The method of claim 14, wherein forming the second cavity includes:
removing a portion of the second fin using an anisotropic etch operation.

19. The method of claim 14, wherein forming the first multi-layer source-drain region and the second multi-layer source-drain region includes:
forming the first multi-layer source-drain region or forming the second multi-layer source-drain region using a series of epitaxial growth operations.

20. The method of claim 14, further comprising:
replacing the first dummy gate with a first gate structure to form a first transistor structure having a first threshold voltage, and
replacing the second dummy gate with a second gate structure to form a second transistor structure having a second threshold voltage that is greater than the first threshold voltage.
